(19) United States
(12) Patent Application Publication
(10) Pub. No.: US 2014/0238475 A1
(43) Pub. Date: Aug. 28, 2014

(54) SOLAR CELL AND FABRICATION METHOD THEREOF

(71) Applicant: AU Optronics Corp., Hsin-Chu (TW)

(72) Inventor: Yen-Cheng Hu, Hsin-Chu (TW)

(73) Assignee: AU Optronics Corp., Hsin-Chu (TW)

(21) Appl. No.: 14/188,632

(22) Filed: Feb. 24, 2014

(30) Foreign Application Priority Data
Feb. 26, 2013 (CN) 201310059480.4

(51) Int. Cl. H01L 31/0224; H01L 31/18

(52) U.S. Cl. CPC H01L 31/022425; H01L 31/18
USPC 136/255; 438/98

(57) ABSTRACT

A solar cell includes a base having a first surface and a second surface opposite to the first surface, a lightly-doped region disposed on the first surface of the base, a semiconductor layer disposed on the lightly-doped region, a first electrode disposed on the first surface of the base, and a second electrode disposed on the second surface of the base. The lightly-doped region has a doping type opposite to the doping type of the base. The bottom of the first electrode is substantially aligned with the interface between the first surface of the base and the lightly-doped region.

### BACKGROUND OF THE INVENTION

1. Field of the Invention

The present invention is related to a solar cell and a fabrication method thereof, and more particularly, to a solar cell with a low potential induced degradation (PID) and high photoelectric conversion efficiency and fabrication method thereof.

2. Description of the Prior Art

The energy in which human beings depend on the most is mainly generated by petroleum resources. However, since the petroleum resources on Earth are limited, the energy demands have shifted toward alternative energies dramatically in recent years. Among the alternative energy sources, solar energy shows the most promising potentials.

Due to the problems such as high cost, process complexity and poor photoelectric conversion efficiency, a breakthrough in the development of solar energy is eagerly expected. Referring to FIG. 1, FIG. 1 is a schematic sectional diagram of a structure of a conventional solar cell module. The solar cell module 10 includes a solar cell 12 surrounded by Ethylene Vinyl Acetate (EVA) 14. The solar cell 12 is fixed in the aluminum frame 16 by a sealant 18. A glass 20 is disposed to cover the surface of the solar cell 12. The solar cell module 10 includes metal electrodes 22, 24 as cathode or anode, a textured surface 26 for decreasing the reflection ratio of light, and a heavily doped emitter disposed on the front side of the solar cell 12. In the conventional structure, when photoelectric conversion occurs to generate currents, it is ideal that electrons should be collected through the emitter and electrodes 22. However, compared to the solar cell 12, the glass 20, EVA 14 and aluminum frame 16 have positive voltage levels, and therefore the recombination current easily occurs on the surface of the material with positive fixed oxide charged (FOC) when the emitters 22 do not have enough time to collect the electrons, resulting in loss of generated currents. This situation is called as potential induced degradation (PID) effect. In addition, the textured surface 26 affect the emitter disposed below to have uneven doping concentration such that the heavily doped emitter itself may also have the problem of high surface recombination. As a result, the structure of a conventional solar cell has the bottleneck with the above-mentioned problems, such as current leakage and low photoelectric conversion efficiency, and it is still one of the important development issues for the manufacturers to develop a solar cell with high photoelectric conversion efficiency.

### SUMMARY OF THE INVENTION

It is one of the objectives of the present invention to provide a solar cell with an emitter disposed inside the structure and a fabrication method thereof, so as to solve the problem of current leakage which may be resulted from PID effect.

According to an embodiment of the present invention, a solar cell is provided. The solar cell includes a base, a lightly-doped area, a semiconductor layer, a first electrode, and a second electrode. The base has a first surface and a second surface opposite to the first surface, wherein the base has a first doping type. The lightly-doped region is disposed on the first surface of the base and has an interface with the first surface of the base. The lightly-doped region has a second doping type which is opposite to the first doping type. The semiconductor layer is disposed above the lightly-doped region and has the first doping type. The first electrode is disposed above the first surface of the base, and a portion of the first electrode is embedded in a portion of the semiconductor layer and a portion of the lightly-doped region, wherein the bottom of the first electrode is substantially at the same horizontal level of the interface between the lightly-doped region and the first surface of the base. The second electrode is disposed on the second surface of the base.

According to an embodiment of the present invention, a fabrication method of the solar cell is further provided. The fabrication method includes providing a substrate having a first surface and a second surface which is opposite to the first surface, wherein the substrate has a first doping type; and forming a lightly-doped region at the first surface of the substrate and forming a semiconductor layer on the lightly-doped region, wherein the lightly-doped region has a second doping type which is opposite to the first doping type and the semiconductor layer has the first doping type. Then, at least one trench is formed in the semiconductor layer. A first electrode is formed on the first surface of the substrate, and a second electrode is formed on the second surface of the substrate, wherein a portion of the first electrode is disposed in the trench and electrically connected to the lightly-doped region.

It is an advantage of the present invention solar cell that the semiconductor layer is disposed above the lightly-doped region that serves as the emitter of the solar cell, so as to prevent the surface recombination which is caused when the emitter is too close to the devices with positive charge, such as the glass and EVA, in the prior-art structure. In addition, the PID effect caused by the recombination current of the heavily-doped emitter in the prior-art structure can also be reduced by taking the lightly-doped region as the emitter of the solar cell, thus the current leakage can be further improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic sectional diagram of a structure of a conventional solar cell module.

FIG. 2 to FIG. 5 are schematic diagrams illustrating the manufacturing process of the fabrication method of the solar cell according to a first embodiment of the present invention.

FIG. 6 to FIG. 9 are schematic diagrams illustrating the manufacturing process of the fabrication method of the solar cell according to a second embodiment of the present invention.

FIG. 10 to FIG. 13 are schematic diagrams illustrating the manufacturing process of the fabrication method of the solar cell according to a third embodiment of the present invention.

FIG. 14 to FIG. 17 are schematic diagrams illustrating the manufacturing process of the fabrication method of the solar cell according to a fourth embodiment of the present invention.

FIG. 18 to FIG. 20 are schematic diagrams illustrating the manufacturing process of the fabrication method of the solar cell according to a fifth embodiment of the present invention.

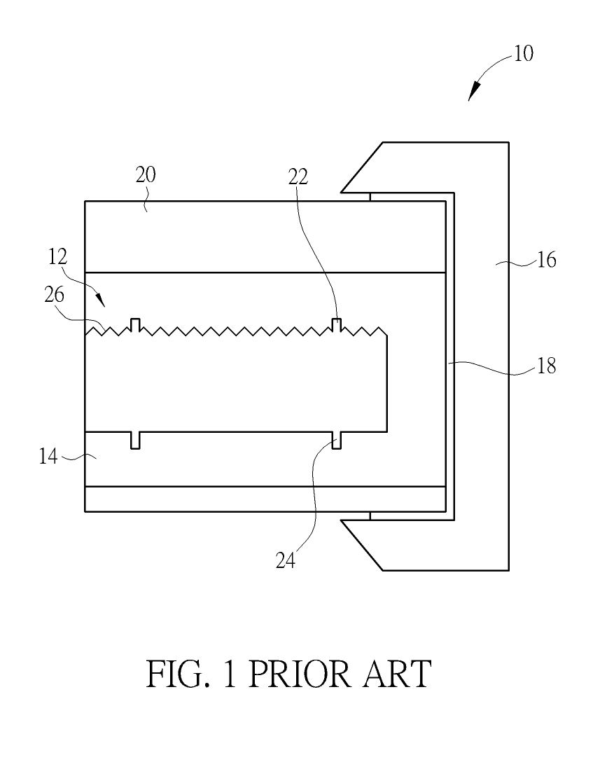

### DETAILED DESCRIPTION

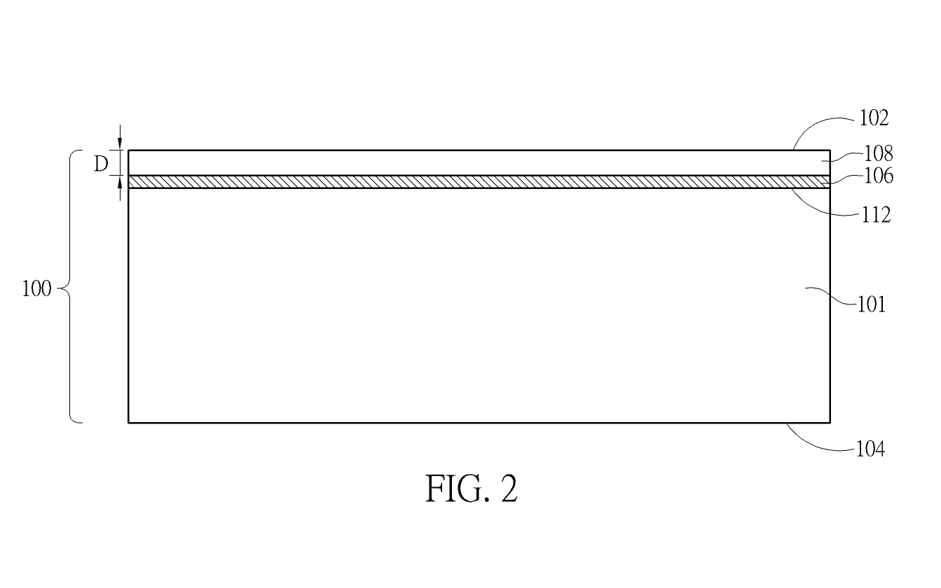

Referring to FIG. 2 to FIG. 5, FIG. 2 to FIG. 5 are schematic diagrams illustrating the manufacturing process of the fabrication method of the solar cell according to a first embodiment of the present invention. As shown in FIG. 2, a substrate 100 with a first doping type is first provided, wherein the substrate 100 may be a semiconductor substrate or a silicon substrate, such as a semiconductor wafer. The substrate 100 has a first surface 102 and a second surface 104 opposite to the first surface 102. Then, a lightly-doped region 106 is formed underneath the first surface 102 of the substrate 100, which maybe formed through an ion shower doping process or an ion-metal-plasma (IMP) process, but not limited thereto. The distance between the lightly-doped region 106 and the first surface 102 is defined as the depth D of the lightly-doped region 106, and may be about 4 to 5 micrometers (pm) for example. An interface 112 is defined between the bottom of the lightly-doped region 106 and the substrate 100. The lightly-doped region 106 has a second doping type which is opposite to the first doping type, and the doping concentration of the lightly-doped region 106 may be, but not limited to, about 1×10¹⁹-²⁰ atom/cm², for example. Since the lightly-doped region 106 is formed underneath the first surface 102 of the substrate 100, it can be deemed that a semiconductor layer 108 with a thickness D is simultaneously formed on the portion of the substrate 100 above the lightly-doped region 106 when forming the lightly-doped region 106. Besides, the portion of the substrate 100 below the lightly-doped region 106 is defined as the base 101, and the first surface of the base 101 is considered as the interface 112 between the base 101 and the lightly-doped region 106.

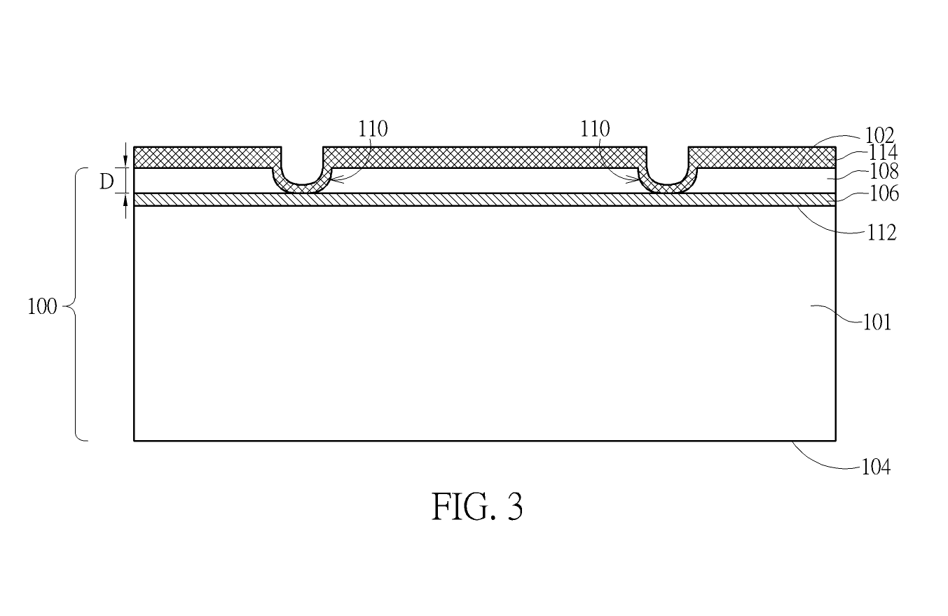

As shown in FIG. 3, then, at least one trench 110 is formed at the first surface 102 of the substrate 100, wherein FIG. 3 shows two trenches 110 for explanation. The trenches 110 maybe formed through a laser grooving process or a photolithography-etching process (PEP) for example, but not limited thereto. The depth of trenches 110 may be approximately the same as the depth D of the semiconductor layer 108, such that the bottoms of the trenches 110 expose a portion of the lightly-doped region 106. Alternatively, the bottoms of the trenches 110 may be in contact with the lightly-doped region 106. Then, an antireflection coating (ARC) layer 114 is selectively formed on the first surface 102 of the substrate 100, which may be formed through a depositing process or a coating process for example. The ARC layer may be only a single layer or include multiple layers, including, but not limited to, at least one of silicon nitride, silicon oxide, silicon oxynitride, zinc oxide, titanium oxide, indium tin oxide (ITO), indium oxide, bismuth oxide, stannic oxide, zirconium oxide, hafnium oxide, antimony oxide, gadolinium oxide, and other suitable materials, or including a combination of at least two of the aforementioned compounds.

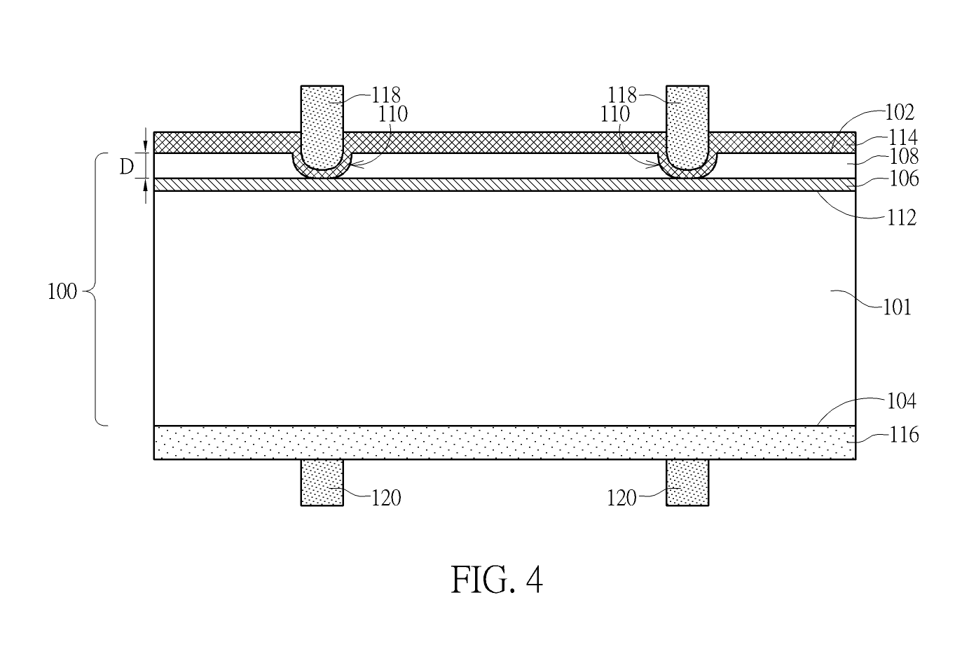

Sequentially, as shown in FIG. 4, at least one first electrode 118 and at least one second electrode 120 including conductive materials are respectively formed on the first surface 102 and the second surface 104 of the substrate 100, wherein two first electrodes 118 and two second electrodes 120 are shown in FIG. 4 as an example. The first electrodes 118 and the second electrodes 120 may respectively include a metal material, such as silver. The first electrodes 118 and the second electrodes 120 may be formed through a screen printing process on the first surface 102 and the second surface 104 of the substrate 100 respectively, and the first electrodes 118 are formed in the trenches 110. It is noteworthy that a metal layer 116 may be selectively formed on the second surface 104 of the substrate 100 before forming the second electrodes 120, wherein the metal layer 116 may include a material of aluminum metal, but not limited thereto.

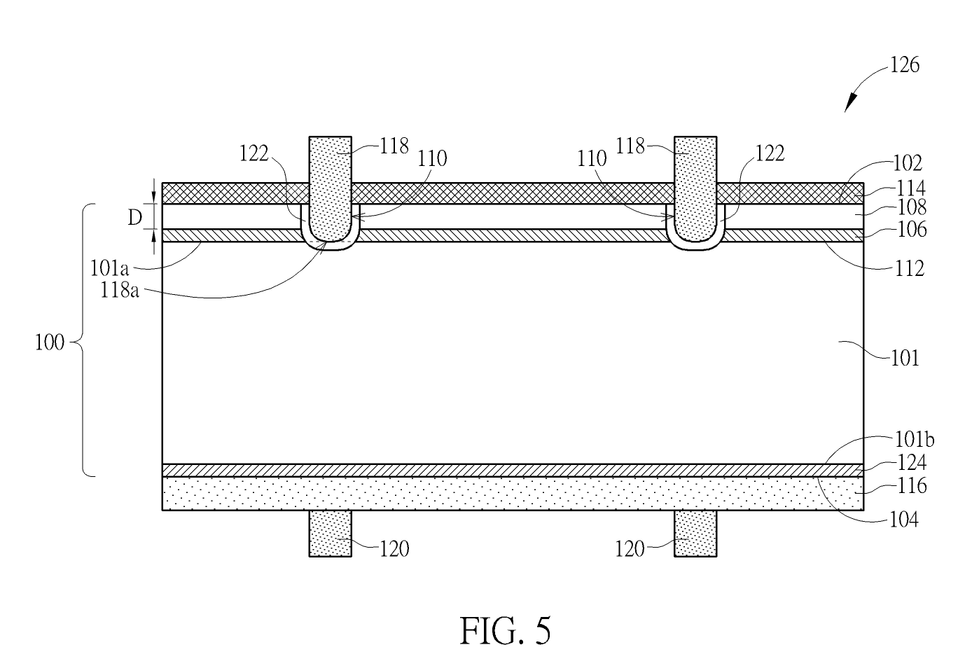

Referring to FIG. 5, a co-firing process is carried out to the substrate 100 to enable the materials of the first electrodes 118 and the second electrodes 120 to act with the semiconductor devices of the substrate 100 and make the conductive materials diffuse toward the internal portion of the substrate 100. Accordingly, the bottoms 118a of the first electrodes 118 are substantially aligned with the interface 112 between the bottom of the lightly-doped region 106 and the base 101 after the co-firing process, which means that the bottoms 118a of the first electrodes 118 and the interface 112 is at the same horizontal level or the vertical height difference between the bottoms 118a of the first electrodes 118 and the interface 112 is not greater than the thickness of the lightly-doped region 106. As a result, each first electrode 118 is electrically connected to the lightly-doped region 106. In addition, after the co-firing process, an ohmic contact layer 122 having metal silicide is formed between each first electrode 118 and the substrate 100 by the reaction of the conductive material of the first electrode 118 with the ARC layer 114, the semiconductor layer 108, and the lightly-doped region 106, wherein the ohmic contact layer 122 maybe seemed as apart of the first electrode 118. In another aspect, after the co-firing process, the material of the metal layer 116 also reacts with the substrate 100 to form a doped region 124 including metal silicide, near the second surface 104 of the substrate 100 and disposed between the first electrodes 120 and the base 101. The doped region 124 has the first doping type, whose material may include alloy of aluminum and silicon. Alternatively, a texturing treatment process may be selectively performed to the first surface 102 of the substrate 100 to form a texturing structure (not shown) on the surface of the ARC layer 114, wherein the texturing structure is disposed above the lightly-doped region 106 in order to decrease the reflection rate of light and increase the light absorption efficiency.

Accordingly, the solar cell 126 according to the fabrication method of the present invention solar cell is shown in FIG. 5. The solar cell 126 includes a base 101, a lightly-doped region 106, a semiconductor layer 108, at least one first electrode 118, and at least one second electrode 120. The base 101 has a first doping type. The bottom of the lightly-doped region 106 and the top surface 101a of the base 101 have a interface 112 therebetween, and the lightly-doped region 106 is disposed on the top surface 101a of the base 101. The lightly-doped region 106 has a second doping type opposite to the first doping type, serving as the emitter of the solar cell 126. The semiconductor layer 108 is disposed above the lightly-doped region 106 and has the first doping type. In addition, the solar cell 126 includes at least one trench 110 disposed on the top surface 101a of the base 101, and the first electrode 118 is disposed in the trench 110 and embedded in a portion of the semiconductor layer 108 and in a portion of the lightly-doped region 106. Furthermore, the bottom 118a of the first electrode 118 is substantially aligned with the interface 112 between the lightly-doped region 106 and the top surface 101a of the base 101. In anther aspect, the second electrode 120 is disposed on the bottom surface 101b of the base 101. The metal layer 116 and the doped region 124 are selectively disposed at the bottom surface 101b of the base 101, between the bottom surface 101b of the base 101 and the second electrode 120.

In this embodiment, the base 101, the semiconductor layer 108, and the doped region 124 all have the first doping type, and the lightly-doped region 106 has the second doping type that is opposite to the first doping type. For instance, the base 101 and the semiconductor layer 108 may have P doping type, the lightly-doped region 106 has N+ doping type, and the doped region 124 has P− doping type, serving as a back side field (BSF) device of the solar cell 126, but not limited thereto. In other embodiments, the base 101 and the semiconductor layer 108 may have N doping type, the lightly-doped region 106 has P+ doping type, and the doped region 124 has N− doping type. The semiconductor layer 108 disposed on the surface of the lightly-doped region 106 serving as the emitter of the solar cell 126 prevents electrons produced in the photoelectric conversion from attracting by any external devices or elements with positive charges to cause recombination at the whole surface of the ARC layer 114, so as to reduce the PID effect and avoid the surface recombination effect and the problem of the doped layer having uneven dopants caused by the heavily-doped layer disposed on the surface of the substrate 100 in the conventional solar cell. As a result, the first electrode 118 of the present invention can effectively collect electrons, and the whole efficiency of the solar cell 126 is therefore raised.

The solar cell of the present invention and the fabrication method thereof are not limited by the aforementioned embodiment, and may have other different preferred embodiments and variant embodiments. To simplify the description, the identical components in each of the following embodiments are marked with identical symbols. For making it easier to compare the difference between the embodiments, the following description will detail the dissimilarities among different embodiments and the identical features will not be redundantly described.

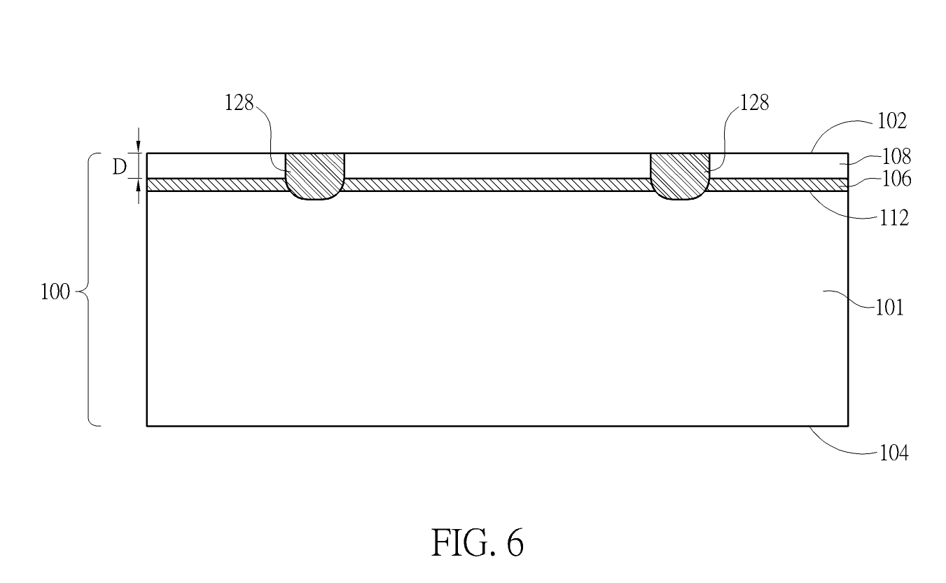

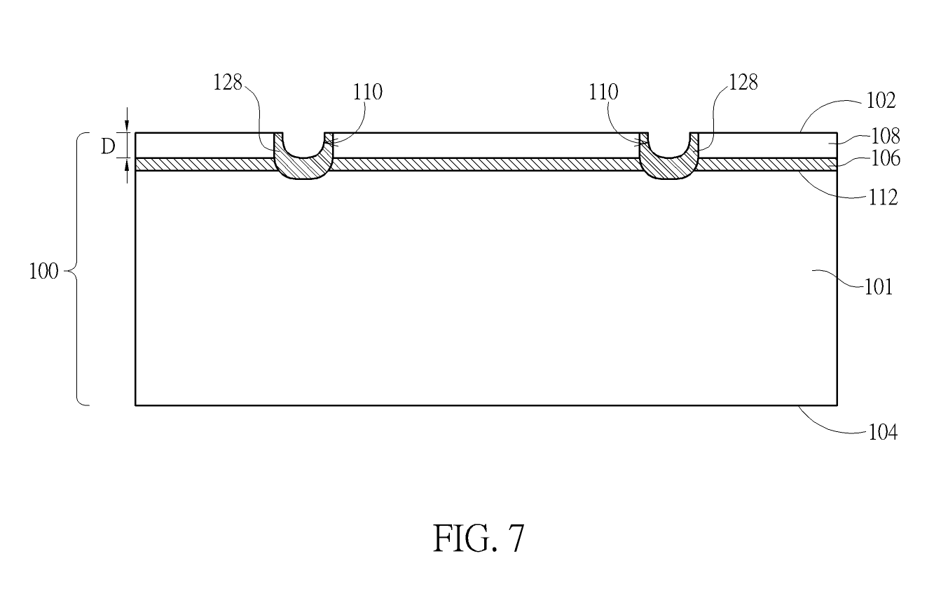

FIG. 6 to FIG. 9 are schematic diagrams illustrating the manufacturing process of the fabrication method of the solar cell according to a second embodiment of the present invention, wherein FIG. 6 illustrates the following processes after the process shown in FIG. 2. As shown in FIG. 6, after forming the lightly-doped region 106, a heavily-doped region 128 is formed in a portion of the first surface 102 of the substrate 100. The heavily-doped region 128 is located in the semiconductor layer 108 and the lightly-doped region 106 and has the second doping type, in which a doping concentration may be about 1×10²⁰atom/cm², for example. The depth of the heavily-doped region 128 is preferably greater than the depth of the interface 112 of the bottom of the lightly-doped region 106 and the substrate 100. The heavily-doped region 128 may be formed by implanting phosphorous ions into the first surface 102 of the substrate 100 through an ion shower doping process or an IMP process and performing an annealing process. The location of the heavily-doped region 128 is the same as the predetermined location of the first electrode on the first surface 102. As shown in FIG. 7, then, a portion of the first surface 102 having the heavily-doped region 128 is removed to form the trenches 110 by a laser grooving process or an etching process for example, which means a portion of the heavily-doped region 128 is removed. The bottoms of the trenches 110 may be approximately at the same horizontal level of the top of the lightly-doped region 106, and a portion of the heavily-doped region 128 are left around the bottoms of the trenches 110.

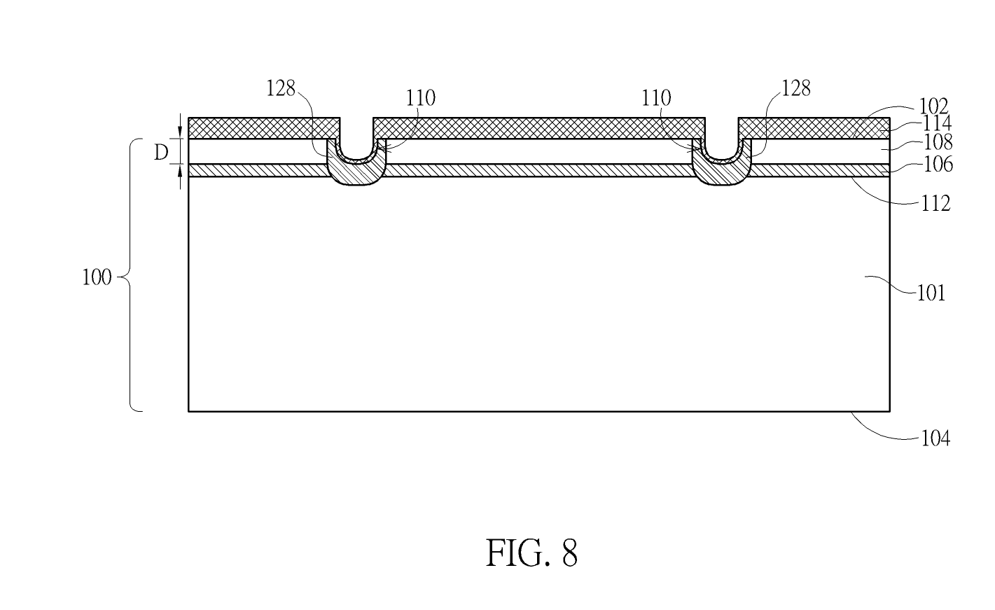

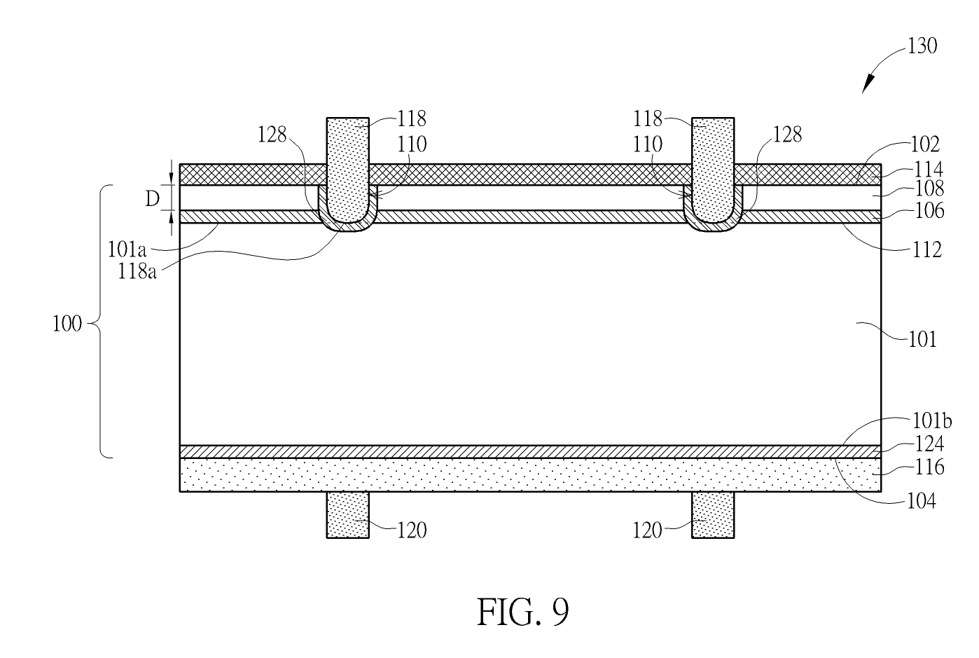

Referring to FIG. 8, an ARC layer 114 is sequentially formed on the first surface 102 of the substrate 100, wherein the ARC layer 114 covers the first surface 102 and the inner surface of the trenches 110, which means the surface of the exposed heavily-doped region 128 is also covered by the ARC layer 114. The ARC layer 114 may include the same material(s) mentioned in the first embodiment, thus no details will be repeated herein. Referring to FIG. 9, as the processes described in FIG. 4 to FIG. 5 of the first embodiment, the metal layer 116 is selectively formed on the second surface 104 of the substrate 100, and then the first electrodes 118 in the trenches 110 and the second electrodes 120 on the second surface 104 of the substrate 100 are formed respectively. After a co-firing process, the doped region 124 is formed at the interface of the metal layer 116 and the substrate 100, and the metal material of the first electrodes 118 in the trenches 110 is diffused downward. After the co-firing process, the bottoms 118a of the first electrodes 118 are substantially aligned with the interface 112 between the bottom of the lightly-doped region 106 and the substrate 100, and the first electrodes 118 are in contact with and electrically connected to the heavily-doped region 128. The heavily-doped region 128 is disposed between the first electrodes 118 and the semiconductor layer 108, the lightly-doped region 106 and the base 101. Accordingly, the fabrication of the solar cell 130 of the second embodiment of the present invention is accomplished. Different from the previous embodiment, the bottoms 118a of the first electrodes 118 of the solar cell 130 are surrounded by the heavily-doped region 128 respectively, and the first electrodes 118 and the heavily-doped region 128 are electrically connected to each other. In this design, the electrons produced from the photoelectric conversion can be even more effectively collected by the first electrodes 118 through the heavily-doped region 128, so as to provide photoelectric current.

Similar to the first embodiment, all of the base 101, the semiconductor layer 108, and the doped region 124 have the first doping type, while the lightly-doped region 106 and the heavily-doped region 128 have the second doping type opposite to the first doping type. For instance, the base 101 and the semiconductor layer 108 may have P doping type, the lightly-doped region 106 have N+ doping type, the heavily-doped region 128 has N++ doping type, and the doped region 124 has P− doping type, but not limited thereto. In other embodiments, the base 101 and the semiconductor layer 108 may have N doping type, the lightly-doped region 106 has P+ doping type, the heavily-doped region 128 has P++ doping type, and the doped region 124 has N− doping type.

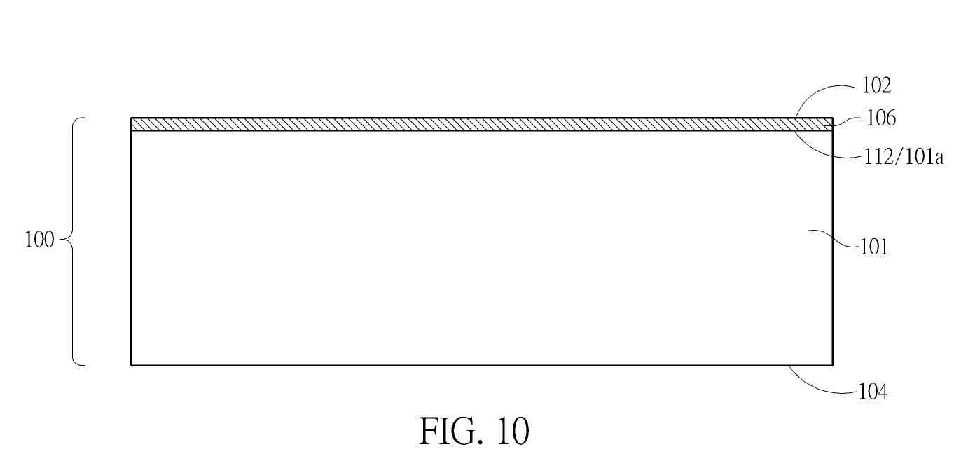

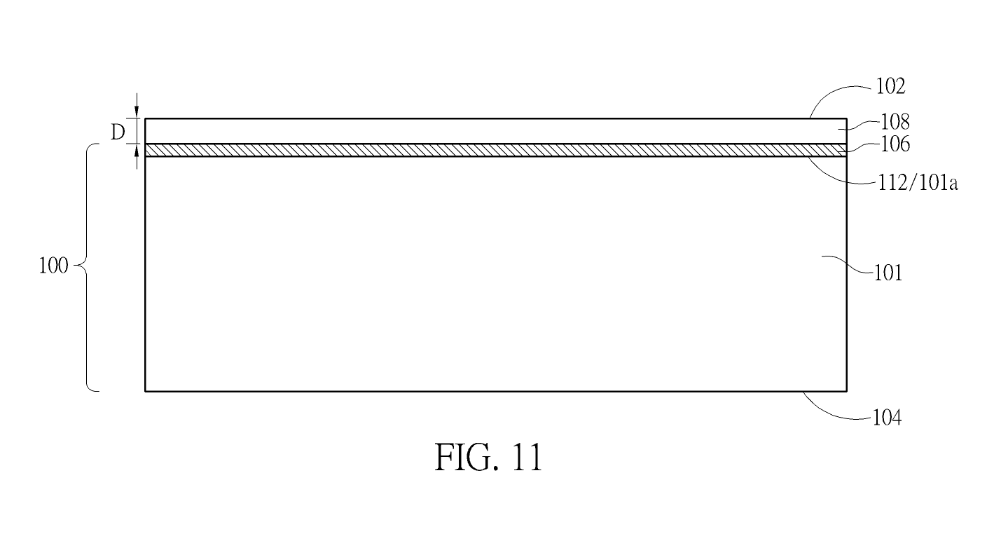

FIG. 10 to FIG. 13 are schematic diagrams illustrating the manufacturing process of the fabrication method of the solar cell according to a third embodiment of the present invention. As shown in FIG. 10, a substrate 100 is provided, and the substrate 100 has a first surface 102 and a second surface 104 opposite to each other. The substrate 100 has a first doping type, such as P doping type. A lightly-doped region 106 is then formed on the first surface 102 of the substrate 100, through a diffusion process by diffusing ions into the first surface 102 of the substrate 100. Therefore, the lightly-doped region 106 is formed at the first surface 102 and within the surface layer of the substrate 100, for example. The bottom of the lightly-doped region 106 and the substrate 100 have an interface 112, and the part of the substrate 100 below the lightly-doped region 106 is considered as abase 101. The interface between the top surface 101a of the base 101 and the lightly-doped region 106 is the above-mentioned interface 112. The lightly-doped region 106 has a second doping type that is opposite to the first doping type, such as N+ doping type. Then, as shown in FIG. 11, a semiconductor layer 108 is formed on the lightly-doped region 106 through an epitaxy process for example, which includes crystalline silicon material. The semiconductor layer 108 preferably has the first doping type, such as P doping type. In addition, the thickness of the semiconductor layer 108 is about 4 μm to 5 μm for example, which may be seen as the depth D of the lightly-doped region 106.

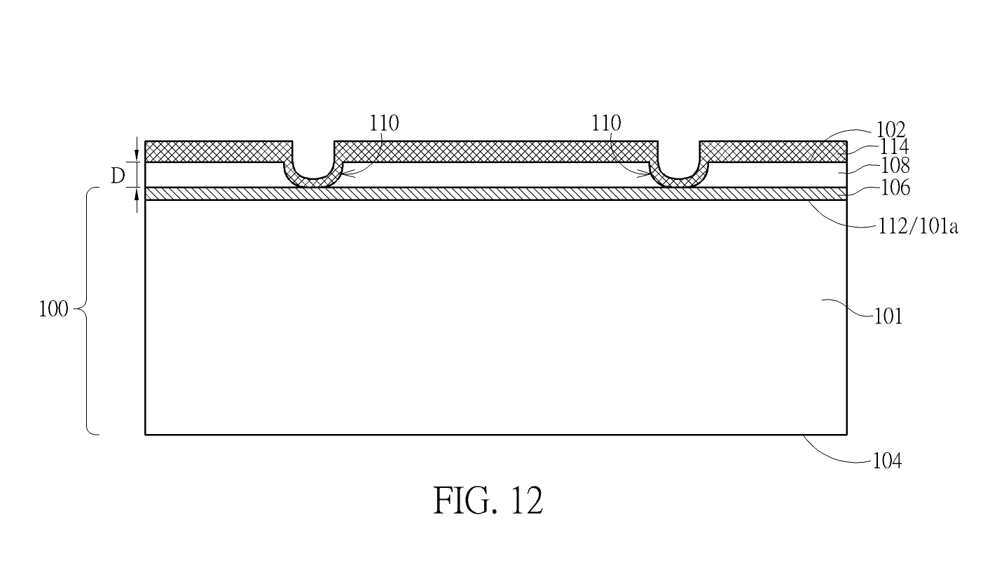

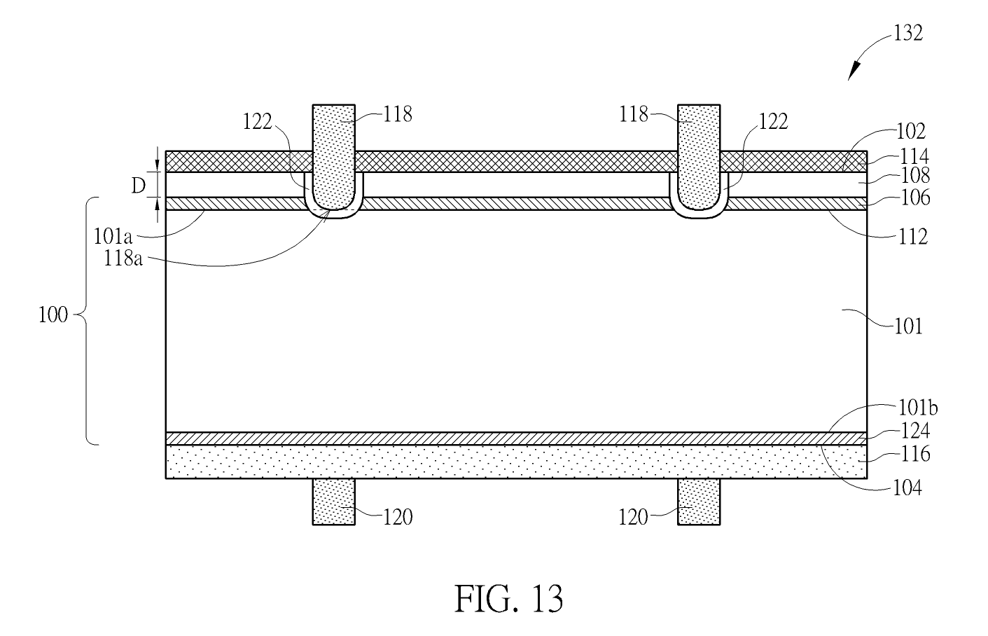

Then, referring to FIG. 12, at least one trench 110 is formed in the semiconductor layer 108 through a laser grooving process or an etching process for example, wherein FIG. 12 shows two trenches 110 for explanation. An ARC layer 114 is following formed on the surfaces of the semiconductor layer 108 and the trenches 110 to cover the surfaces of the semiconductor layer 108 and the trenches 110. Sequentially, referring to FIG. 13, several processes in the previous embodiments are adopted to form the first electrodes 118 in the trenches 110 and the second electrodes 120 on the second surfaces 104 of the substrate 100. In addition, an ohmic contact layer 122 is formed between the first electrodes 118 and the semiconductor layer 108 and between the first electrodes 118 and the lightly-doped region 106. In addition, a metal layer 116 may be selectively formed on the second surface 104 of the substrate 100, and a doped region 124 is formed after a co-firing process, disposed between the metal layer 116 and the base 101. The doped region 124 has the first doping type. Similarly, in this embodiment, the bottoms 118a of the first electrodes 118 are substantially aligned with the interface 112 between the bottom of the lightly-doped region 106 and the substrate 100. Accordingly, the fabrication of the solar cell 132 of the third embodiment of the present invention is accomplished. Different from the previous embodiments, the lightly-doped region 106 is formed on the surface of the substrate 100 and then the semiconductor layer 108 is formed on the lightly-doped region 106 in this embodiment.

As a result, FIG. 13 illustrates the solar cell 132 fabricated according to the fabrication method of the third embodiment of the present invention, wherein the solar cell 132 includes the base 101, the lightly-doped region 106, the semiconductor layer 108, the first electrodes 118, and the second electrodes 120. The base 101 has the first doping type. The bottom of the lightly-doped region 106 and the top surface 101a of the base 101 have an interface 112, and the lightly-doped region 106 is disposed on the top surface 101a of the base 101. The lightly-doped region 106 has the second doping type opposite to the first doping type, for serving as the emitter of the solar cell 126. The semiconductor layer 108 is disposed above the lightly-doped region 106 and has the first doping type. In addition, the solar cell 132 includes at least one trench 110 disposed above the top surface 101a of the base 101 and at least one first electrode 118 disposed in the trench 110, wherein at least a portion of the first electrode 118 is embedded in a portion of the semiconductor layer 108 and in a portion of the lightly-doped region 106. The bottom 118a of the first electrode 118 is substantially aligned with the interface 112 between the lightly-doped region 106 and the top surface 101a of the base 101. In another aspect, on the bottom surface 101b of the base 101, at least one second electrode 120 is disposed, and the metal layer 116 and the doped region 124 are selectively formed, wherein the doped region 124 and the metal layer 116 are disposed between the bottom surface 101b of the base 101 and the second electrode 120.

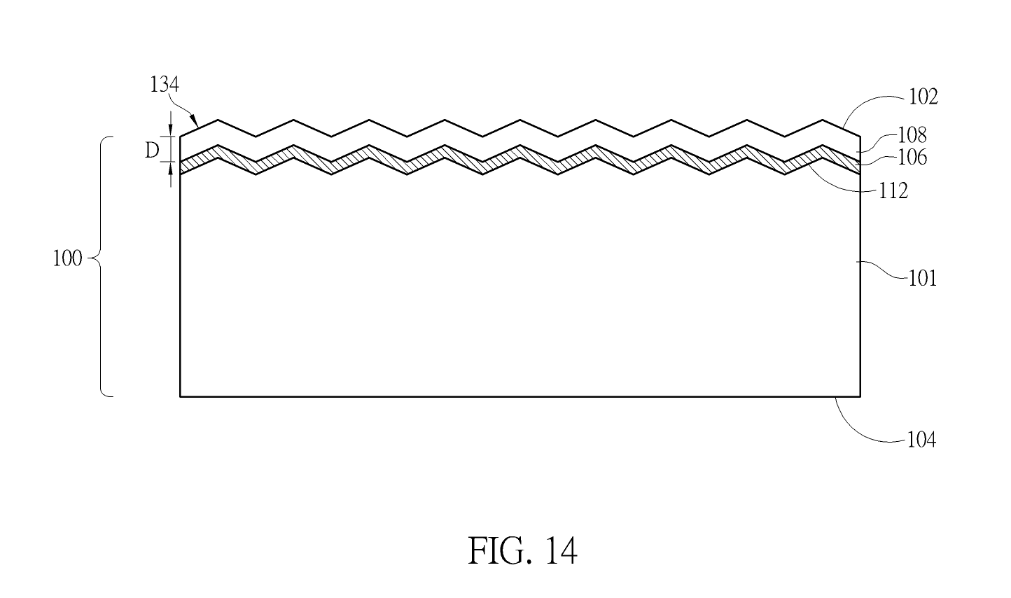

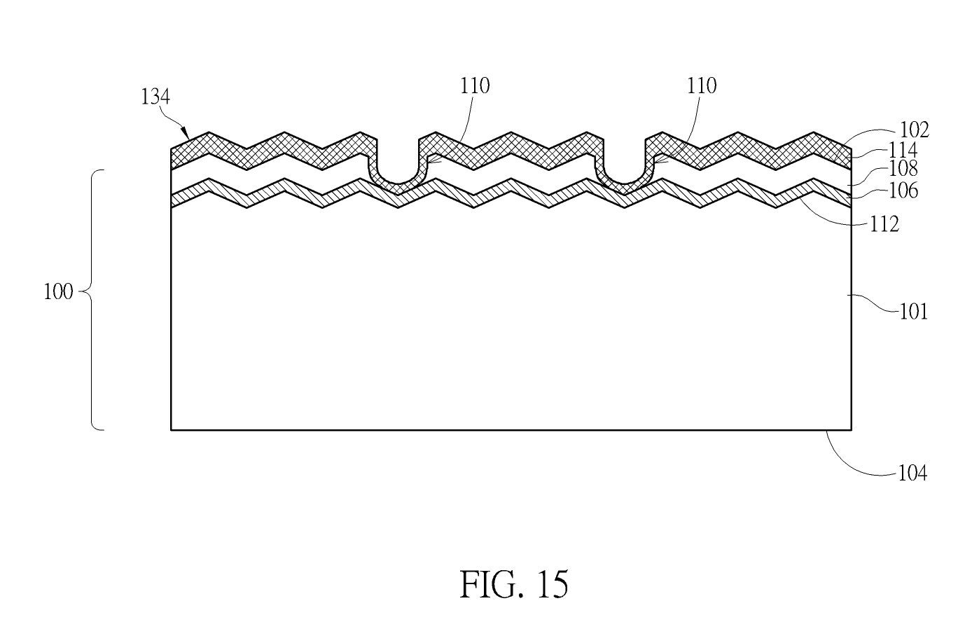

Referring to FIG. 14 to FIG. 17, FIG. 14 to FIG. 17 are schematic diagrams illustrating the manufacturing process of the fabrication method of the solar cell according to a fourth embodiment of the present invention. Different from the previous embodiments, a texturing structure is first formed on the surface of the substrate in this embodiment before forming other devices of the solar cell. As shown in FIG. 14, first, a substrate 100 including at least a semiconductor material is provided, wherein the substrate 100 has a first doping type. A texturing treatment process is performed to the first surface 102 of the substrate 100 to form the texture structure 134. Then, the lightly-doped region 106 is formed below the first surface 102 of the substrate 100 through an ion implanting process or an IMP process, wherein the depth D of the lightly-doped region 106 in the substrate 100 is about 4 μm to 5 μm for example. The portion of the substrate 100 disposed below the lightly-doped region 106 can be seen as the base 101, and the portion of the substrate 100 disposed above the lightly-doped region 106 can be seen as the semiconductor layer 108. Therefore, the thickness of the semiconductor layer 108 is the same as the depth D of the lightly-doped region 106. In addition, the lightly-doped region 106 has a second doping type opposite to the first doping type. Then, as shown in FIG. 15, the trenches 110 are formed in the first surface 102 of the substrate 100, wherein the bottoms of the trenches 110 are approximately in contact with the top of the lightly-doped region 106. Sequentially, the ARC layer 114 is formed on the first surface 102 of the substrate 100, covering the surfaces of the first surface 102 of the substrate 100 and the trenches 110.

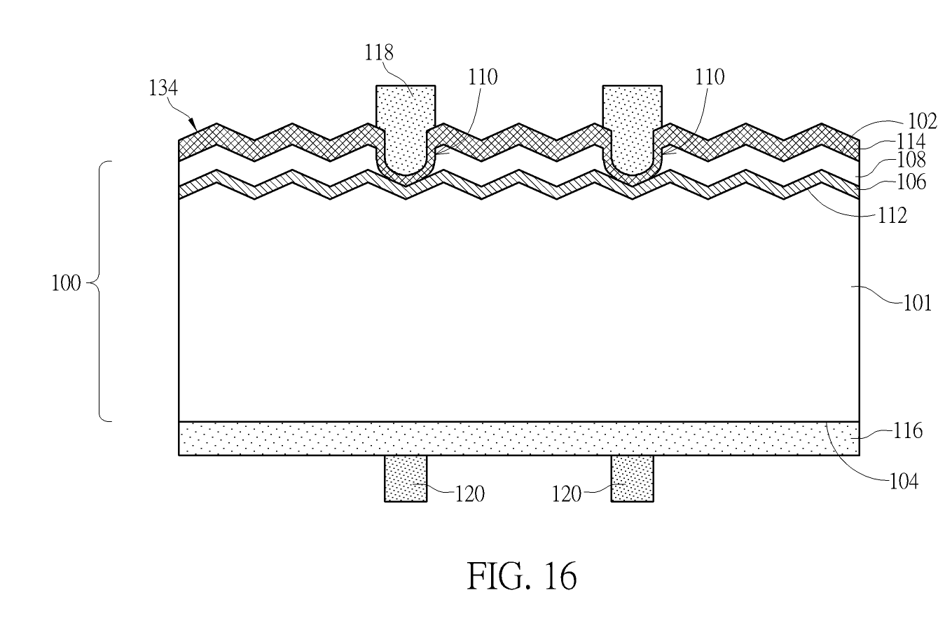

Then, referring to FIG. 16, the first electrodes 118 and the second electrodes 120 are respectively formed on the first surface 102 and the second surface 104 of the substrate 100, wherein the first electrodes 118 and the second electrodes 120 preferably include metal materials, such as silver. A screen printing process may be adopted for forming the first electrodes 118 and the second electrodes 120 in the trenches 110 and on the second surface 104 of the substrate 100 respectively. It is noteworthy that the metal layer 116 may be selectively formed on the second surface 104 of the substrate 100 before forming the second electrodes 120, wherein the material of the metal layer 116 is, for example, aluminum, but not limited thereto.

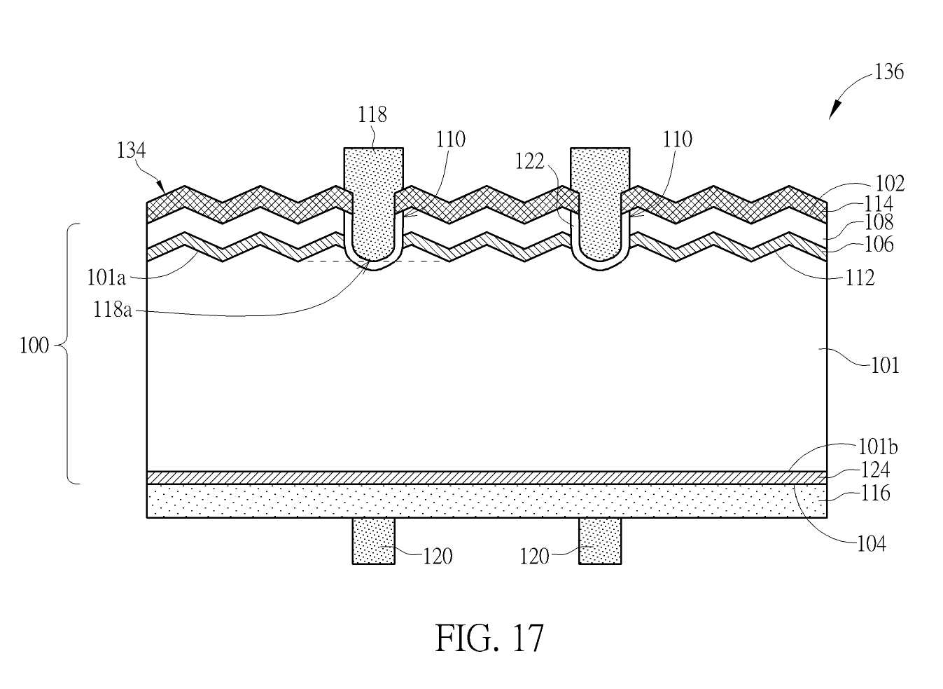

Referring to FIG. 17, a co-firing process to the substrate 100 is then performed to enable the metal materials of the first electrodes 118 and the second electrodes 120 to react with the semiconductor devices on the substrate 100 and to diffuse inward in the substrate 100. Therefore, after the co-firing process, the bottoms 118a of the first electrodes 118 are substantially aligned with the interface 112 between the bottom of the lightly-doped region 106 and the substrate 100. The description that the bottoms 118a of the first electrodes 118 are substantially aligned with the interface 112 means that each bottom 118a and the interface 112 are at the same horizontal level or that the vertical height difference or a drop height between each bottom 118a and the interface 112 is less than or equal to the thickness of the lightly-doped region 106. In addition, the ohmic contact layer 122 including metal silicide is formed between the first electrodes 118 and the substrate 100 because the metal material of the first electrodes 118 reacts with the ARC layer 114, the semiconductor layer 108, and the lightly-doped region 106 during the co-firing process. The doped region 124 including metal silicide is also formed near the second surface 104 of the substrate 100 and is disposed between the second electrodes 120 and the substrate 100 since the metal layer 116 reacts with the material of the substrate 100 during the co-firing process. The doped region 124 has the first doping type, such as P doping type . Accordingly, the fabrication of the solar cell 136 of the fourth embodiment of the present invention is accomplished.

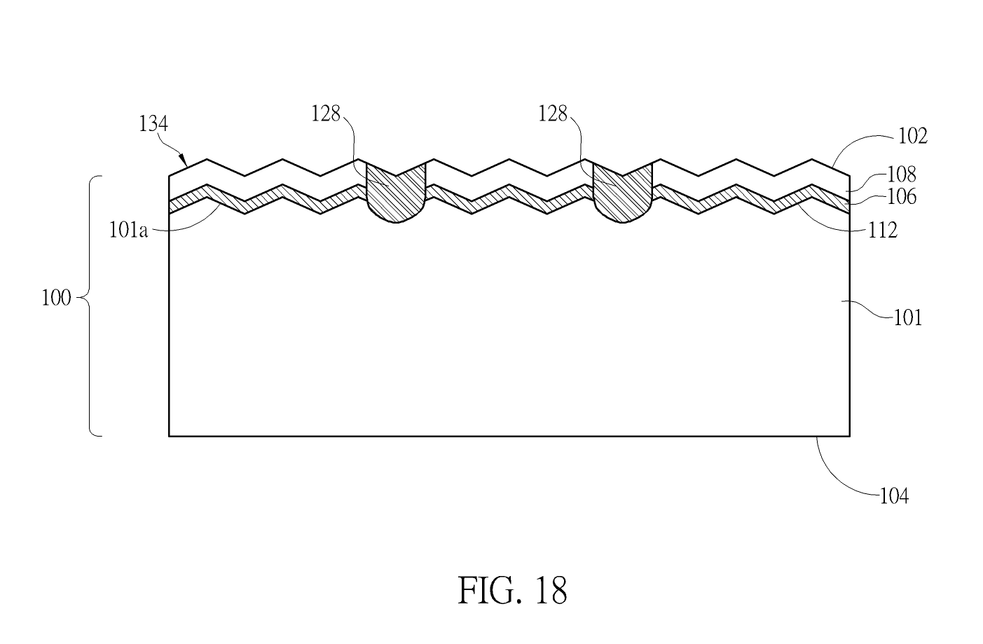

Referring to FIG. 18 to FIG. 20, FIG. 18 to FIG. 20 are schematic diagrams illustrating the manufacturing process of the fabrication method of the solar cell according to a fifth embodiment of the present invention. FIG. 18 shows the structure in the fabrication after the manufacturing processes of FIG. 14 of the fourth embodiment. Different from the fourth embodiment, a heavily-doped region is formed in the substrate 100 before forming the trench in this embodiment. As shown in FIG. 18, after the lightly-doped region 106 is formed, at least one heavily-doped region 128 is formed in a portion of the first surface 102 of the substrate 100, wherein the heavily-doped region 128 has the second doping type such as N++ doping type, whose doping type is the same as the lightly-doped region 106. The doping concentration is about 1×10²⁰atom/cm² for example. The depth of the bottom of the heavily-doped region 128 is preferably greater than the depth of the interface 112 of the bottom of the lightly-doped region 106 and the substrate 100. The heavily-doped region 128 may be formed through, for instance, an ion shower doping process or an IMP process and a following annealing process, wherein the ion shower doping process or the IMP process is used to implant phosphorous ions into the first surface 102 of the substrate 100. The location of the heavily-doped region 128 is the predetermined locations of the first electrodes on the first surface 102 of the substrate 100.

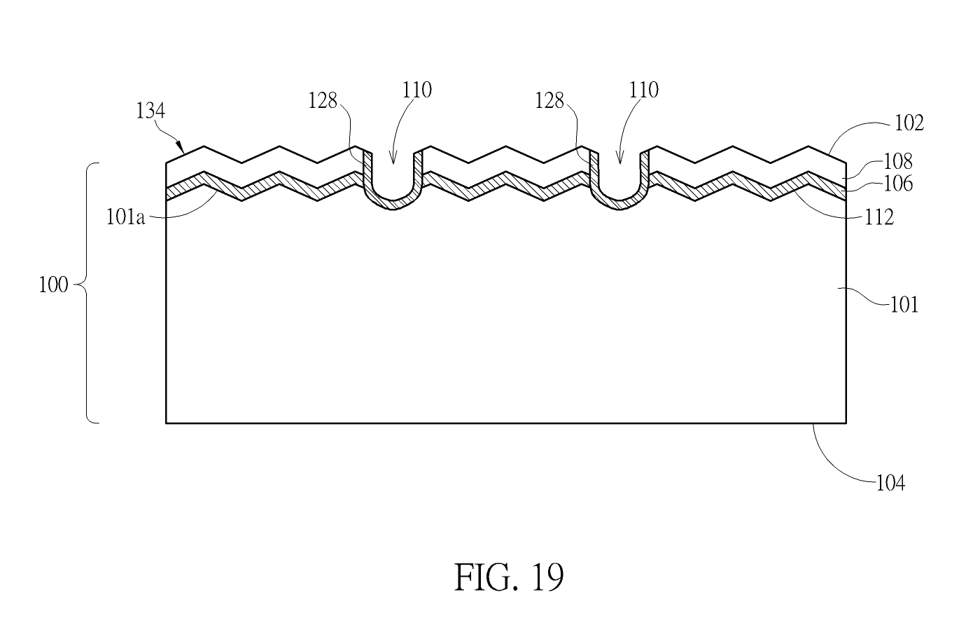

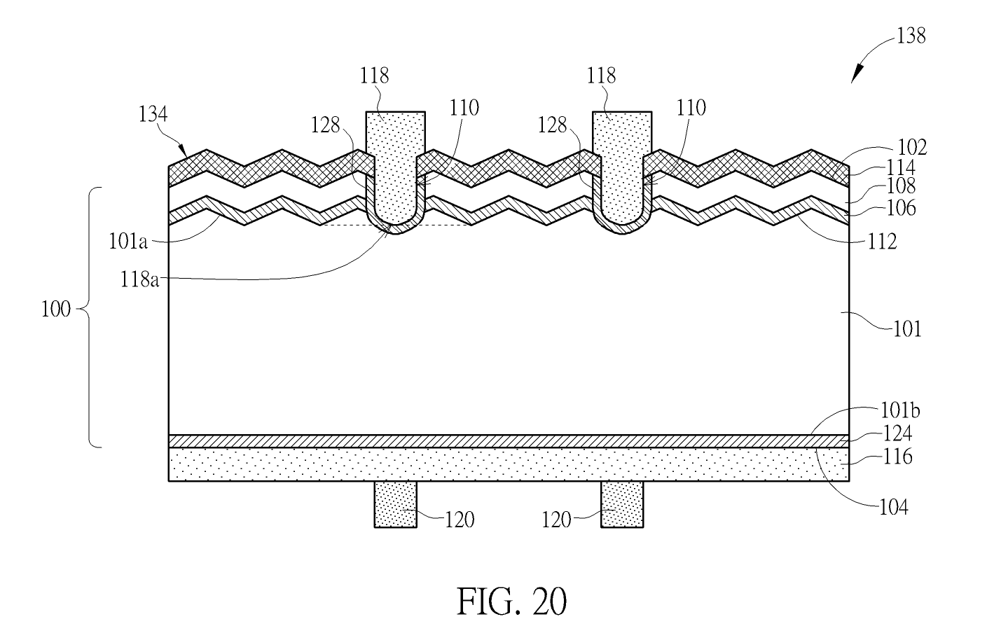

As shown in FIG. 19, a laser grooving process or an etching process may be performed to remove a portion of the heavily-doped region 128 to form the trenches 110 in the heavily-doped region 128, wherein the bottoms of the trenches 110 and the top of the lightly-doped region 106 may be approximately disposed at the same horizontal level, and a portion of the heavily-doped region 128 are left around the bottoms of the trenches 110. Referring to FIG. 20, an ARC layer 114 is selectively formed on the first surface 102 of the substrate 100, wherein the ARC layer 114 covers the first surface 102 and the inner surfaces of the trenches 110, which means the exposed surface of the heavily-doped region 128 is covered by the ARC layer 114. The ARC layer 114 may include any materials mentioned in the first embodiment, and the details will not be repeated herein. Then, similar to the processes illustrated in FIG. 16 to FIG. 17 of the fourth embodiment, a metal layer 116 is selectively formed on the second surface 104 of the substrate 100, and the first electrodes 118 and the second electrodes 120 are formed in the trenches 110 and on the second surface 104 of the substrate 100 respectively. After a co-firing process, a doped region 124 is formed between the metal layer 116 and the substrate 100. Furthermore, the metal material of the first electrodes 118 in the trenches 110 is diffused inward and reacts with other devices on the substrate 100 during the co-firing process such that the bottom 118a of the first electrode 118 is substantially aligned with the interface 112 between the bottom of the lightly-doped region 106 and the substrate 100. Therefore, the solar cell 138 of the fifth embodiment of the present invention is accomplished.

According to the present invention solar cell, the lightly-doped region serving as the emitter is disposed below the semiconductor layer, not disposed on the top surface of the whole solar cell structure or directly in contact with the ARC layer, such that the present invention solar cell has low surface recombination current and the problem caused from the PID effect can be solved. Moreover, since the lightly-doped region serving as the emitter is not disposed along the texturing structure, it can have a more uniform doping concentration. As a result, the present invention solar cell and the fabrication method thereof provide a solar cell structure having higher photoelectric conversion efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar cell, comprising:
abase having a first surface and a second surface which is opposite to the first surface, wherein the base has a first doping type;
a lightly-doped region disposed on the first surface of the base, an interface occurring between the lightly-doped region and the first surface of the base, wherein the lightly-doped region has a second doping type which is opposite to the first doping type;
a semiconductor layer disposed above the lightly-doped region, wherein the semiconductor layer has the first doping type;
a first electrode disposed above the first surface of the base, a portion of the first electrode is embedded in a portion of the semiconductor layer and in a portion of the lightly-doped region, wherein a bottom of the first electrode is substantially aligned with the interface between the lightly-doped region and the first surface of the base; and
a second electrode disposed on the second surface of the base.

2. The solar cell of claim 1, further comprising a heavily-doped region disposed between the first electrode and the semiconductor layer, the lightly-doped region, and the base, wherein the heavily-doped region has the second doping type and the first electrode is disposed on the heavily-doped region.

3. The solar cell of claim 1, further comprising a doped region disposed on the second surface of the base and between the second electrode and the base.

4. The solar cell of claim 3, wherein the doped region has the first doping type.

5. The solar cell of claim 1, further comprising an antireflection coating (ARC) layer disposed above the semiconductor layer.

6. The solar cell of claim 1, wherein the first surface of the base has a textured structure.

7. A fabrication method of a solar cell, comprising:
providing a substrate having a first surface and a second surface, the first surface being opposite to the second surface, wherein the substrate has a first doping type;
forming a lightly-doped region at the first surface of the substrate and a semiconductor layer having the first doping type above the lightly-doped region, wherein the lightly-doped region has a second doping type opposite to the first doping type;
forming at least one trench in the semiconductor layer; and
forming a first electrode at the first surface of the substrate and a second electrode at the second surface of the substrate, a portion of the first electrode being disposed in the trench and electrically connected to the lightly-doped region.

8. The fabrication method of the solar cell of claim 7, further comprising performing a co-firing process to the substrate after the step of forming the first electrode and the second electrode, wherein a bottom of the first electrode is substantially aligned with a bottom of the lightly-doped region after the co-firing process.

9. The fabrication method of the solar cell of claim 7, further comprising forming a doped region at the second surface of the substrate, the doped region being disposed between the second electrode and the substrate and having the first doping type.

10. The fabrication method of the solar cell of claim 7, further comprising forming a heavily-doped region at the first surface of the substrate, wherein the heavily-doped region is disposed in the semiconductor layer and the lightly-doped region, and has a second doping type, and the step of forming the trench is performed by a laser grooving process to remove a portion of the heavily-doped region for forming the trench.

11. The fabrication method of the solar cell of claim 10, wherein the step of forming the first electrode further comprises forming the portion of the first electrode in the trench positioned in the heavily-doped region, and the first electrode is in contact with and electrically connected to the heavily-doped region.

12. The fabrication method of the solar cell of claim 7, wherein the semiconductor layer and the lightly-doped region are formed simultaneously, the step of forming the lightly-doped region includes performing anion shower doping process or an ion-metal-plasma (IMP) process to form the lightly-doped region at a predetermined depth of the substrate and therefore a portion of the substrate above the lightly-doped region constitutes the semiconductor layer simultaneously.

13. The fabrication method of the solar cell of claim 7, wherein the step of forming the lightly-doped region includes a diffusion process.

14. The fabrication method of the solar cell of claim 13, wherein the semiconductor layer is formed through an epitaxy depositing process.

15. The fabrication method of the solar cell of claim 7, further comprising forming an ARC layer on the semiconductor layer.

16. The fabrication method of the solar cell of claim 7, further comprising forming a texturing structure at the first surface of the substrate.

17. The fabrication method of the solar cell of claim 7, wherein the trench is formed through a laser grooving process.
